(19) United States
(12) Patent Application Publication
(10) Pub. No.: US 2026/0344342 A1
(43) Pub. Date: Oct. 29, 2026

(54) WAFER MAPPING APPARATUS

(71) Applicant: ASM IP Holding B.V., Almere (NL)

(72) Inventors: Nimit Kothari, Almere (NL); Renée Meijer, Amsterdam (NL); Marina Pogalin, Dronten (NL); Jeroen de Jonge, Almere (NL); Michiel Barend Kalmeijer, Hilversum (NL); Levar Goossen, Amsterdam (NL)

(21) Appl. No.: 19/657,370

(22) Filed: Apr. 24, 2026

Related U.S. Application Data
(60) Provisional application No. 63/796,941, filed on Apr. 29, 2025.

(51) Int. Cl. H10P 72/00; H10P 72/30; H10P 72/50

(52) U.S. Cl. CPC H10P 72/0608; H10P 72/3402; H10P 72/53

(57) ABSTRACT

A wafer mapping apparatus is disclosed. The wafer mapping apparatus includes a light source designed to emit light towards a wafer carrier, imaging means to capture the light that is reflected from the wafer carrier, and a plate arranged to partially obstruct the emitted light.

### CROSS-REFERENCE TO RELATED APPLICATIONS

This application claims priority to U.S. Provisional Patent Application Ser. No. 63/796,941 filed Apr. 29, 2025 titled WAFER MAPPING APPARATUS, the disclosure of which is hereby incorporated by reference in its entirety.

### FIELD

The present disclosure relates generally to the field of semiconductor processing methods, and associated structures and apparatus, and to the field of device and integrated circuit manufacture. More particularly the present disclosure generally relates to wafer mapping tools.

### BACKGROUND

Batch semiconductor processing apparatuses, such as vertical furnaces, provide an alternative to single wafer apparatuses in the manufacturing of semiconductors. One of the primary advantages of batch processing apparatuses is the ability to process multiple wafers simultaneously, thereby increasing productivity and reducing overall production time.

In a batch semiconductor processing apparatus, wafers are typically loaded into a wafer boat, which is then inserted into the process chamber for processing. This approach allows for the efficient processing of multiple wafers in a single cycle, enhancing overall production efficiency. However, it is important to ensure correct wafer positioning within the wafer boat to guarantee uniform processing and prevent any potential defects. Incorrect wafer positioning can occur in various forms, such as overloading of wafer boat slots, where multiple wafers are accommodated at a single slot or support position; cross-slotting of wafers, where wafers are not aligned properly within the wafer boat, leading to uneven processing; and empty slots within the wafer boat, where no wafers are present.

Correcting these errors requires careful monitoring of the wafer boat and the processing apparatus. Maintaining accurate wafer positioning in the boat is essential to ensure consistent processing results and maximize overall throughput.

Therefore there is a need for ensuring accurate positioning of wafers within a wafer boat, so as to achieve improved productivity, reduced production costs, and enhanced product quality.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

According to a first aspect of the present invention, there is provided a wafer mapping apparatus comprising a light source configured to emit light towards a wafer carrier; imaging means configured to receive light emitted by the light source and reflected at the wafer carrier; and a plate arranged to partially obstruct light emitted by the light source.

By providing the plate arranged to partially obstruct light from the light source, a light beam emitted by the light source towards wafers to be mapped can be made narrower in a vertical direction, thereby reducing reflections from other components in the vicinity of the wafer carrier which may otherwise cause noise in an image acquired by the imaging means. This may allow for more accurate mapping of wafer(s) contained in the wafer carrier, due to reduced noise and/or artefacts in the image.

The plate may be moveable so as to vary a degree of obstruction of light emitted by the light source.

The plate may be positioned so as to provide a beam height at the wafer carrier which is less than three times a spacing between adjacent wafer receiving positions in the wafer carrier.

The light emitted by the light source towards the wafer boat may have a beam angle in a horizontal direction of at least ten degrees.

The light source may be positioned above the imaging means.

The light source may be partially supported by the imaging means.

The imaging means and the light source may be partially contained by a support, wherein the plate is attached to the support.

The plate may be attached to the light source.

The light source may comprise a light emitting surface having a width and a height, wherein the width is at least five times the height.

The wafer mapping apparatus may comprise a computer-readable medium on which is stored one or more sets of instructions or software, which, when executed by a computer, cause the computer to perform operations for determining a parameter of an image of a wafer carrier acquired by the imaging means.

The operations may comprise: obtaining an image of a wafer carrier; and detecting a presence or absence of a contour in the image.

The operations may comprise, if a presence of a contour in the image is detected, fitting a line to the contour.

The operations may comprise determining a parameter of the image based on the line fitted to the contour.

The parameter may be indicative of a position of a wafer in the wafer carrier.

According to a second aspect of the present invention there is provided a wafer handling apparatus comprising a wafer handling robot and the wafer mapping apparatus of the first aspect, wherein the one or more sets of instructions or software, when executed by the computer, cause the computer to perform operations for controlling a position of the wafer handling robot in dependence upon the parameter of the image of the wafer carrier.

The wafer handling apparatus according to the second aspect may be configured such that the one or more sets of instructions or software, when executed by the computer, further cause the computer to determine a calibrated exposure time by determining a rate of change of a detected wafer width with respect to exposure time, identifying a first sequence of exposure settings for which the rate of change is below a predetermined threshold value, and selecting the calibrated exposure time from within the first sequence.

According to a third aspect of the present invention there is provided a wafer handling apparatus comprising a wafer handling robot comprising at least two rotatably linked arms, an end effector attached to one of the arms, and an elevator for varying a vertical position of the at least two rotatably linked arms and the end effector; and the wafer mapping apparatus according to the first aspect, wherein the light source, imaging means, and plate are supported on the elevator.

The wafer handling apparatus may further comprise a controller configured to control a position of the wafer mapping apparatus in the vertical direction by controlling the elevator, wherein the controller is further configured to repeat, at least once, the steps of: causing the wafer mapping apparatus to acquire an image of a wafer carrier using the imaging means and to determine a parameter of the image of the wafer carrier; and causing a position of the wafer mapping apparatus in the vertical direction to be changed.

According to a fourth aspect of the present invention there is provided a semiconductor processing apparatus comprising a wafer handling space, wherein the wafer handling space comprises a wafer mapping apparatus according to the first aspect or a wafer handling apparatus according to the second or third aspect.

Other technical features may be readily apparent to one skilled in the art from the following figures, descriptions, and claims.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

Certain embodiments of the present invention will now be described, by way of example, with reference to the accompanying drawings, in which:

FIG. 1 is a schematic horizontal cross-sectional view of a semiconductor processing apparatus for batch processing of a plurality of substrates, which may comprise a wafer mapping apparatus or wafer handling apparatus according to embodiments of the present invention;

FIG. 2 is a schematic perspective view of a wafer mapping apparatus according to embodiments of the present invention;

FIG. 3 is a front view of an imaging means and light source comprised in a wafer mapping apparatus according to embodiments of the present invention;

FIG. 4 is a side view of a wafer mapping apparatus according to embodiments of the present invention and a wafer carrier;

FIG. 5 is a schematic perspective view of a wafer handling apparatus according to embodiments of the present invention;

FIG. 6 is an example image of part of a wafer carrier showing wafers supported in the wafer carrier;

FIG. 7 is an example image of part of a wafer carrier showing wafers supported in the wafer carrier, wherein one wafer receiving position contains two wafers (double slotting).

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

Where in the present disclosure two or more elements are referred to as being “in fluid communication”, it is meant that a fluid such as a gas or liquid or mixture thereof can flow between the elements, in one or both directions. The fluid communication may be achieved, for example, by means of a gas line, tube, pipe, inlet, outlet, or any combination thereof. The fluid communication may be interruptible; for example, a valve or other flow control element may be present.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicate herein can be relative or absolute percentages.

A number of example materials are given throughout the embodiments of the current disclosure, it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film or layer may be directly on a mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

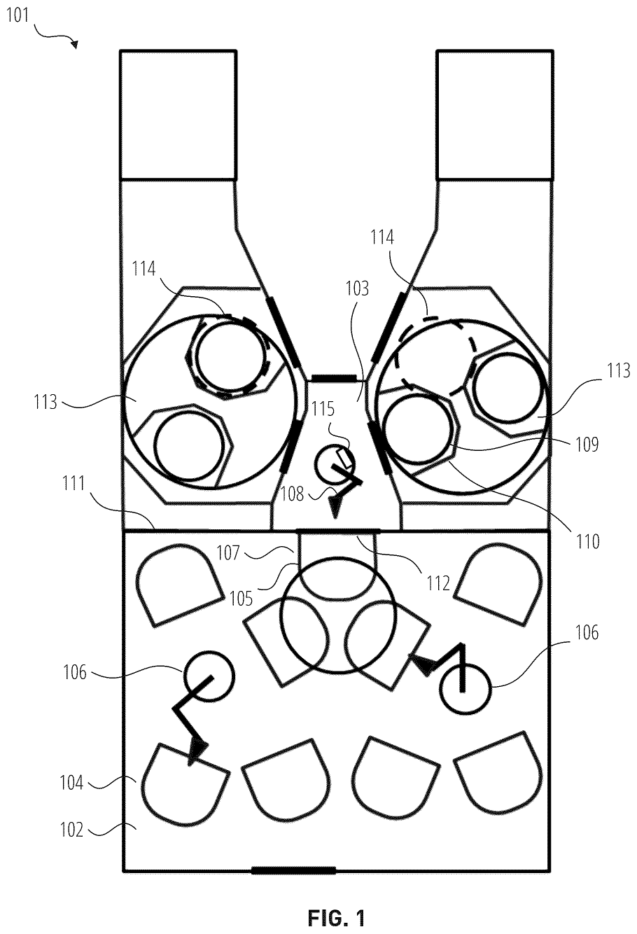

The present invention provides a wafer mapping tool which may be deployed in a wafer handling chamber of a semiconductor processing apparatus. Referring to FIG. 1, a schematic horizontal cross-sectional view of an exemplary semiconductor processing apparatus 101 for batch processing of a plurality of substrates is shown. The semiconductor processing apparatus 101 may be, for example, a vertical furnace. The semiconductor processing apparatus 101 may comprise a cassette handling space 102 and a wafer handling space 103. A wafer mapping apparatus or wafer handling apparatus according to embodiments of the present invention may be comprised in the wafer handling space.

The cassette handling space 102 may be provided with a cassette storage 104 configured to store a plurality of wafer cassettes 105 which may each contain a plurality of wafers. The cassette handling space 102 may be provided with a cassette handler 106 configured to transfer wafer cassette 105 between the cassette storage 104 and a wafer transfer position 107.

The wafer cassettes 105 may be embodied as Front Opening Unified Pods (FOUPs). FOUPs are considered standard enclosures for wafers in the industry. Using FOUPs is advantageous for exchangeability of the wafer cassette 105 between the semiconductor processing apparatus 101 and other semiconductor processing apparatuses 101.

The semiconductor processing apparatus 101 may comprise an internal wall 111 separating the cassette handling space 102 and the wafer handling space 103. The internal wall 111 may be provided with a wafer transfer opening 112 adjacent the wafer transfer position 107 for a wafer cassette 105 from or to which wafers are to be transferred.

The wafer handling space 103 may comprise a wafer handling robot 108 configured to transfer wafers between a wafer cassette 105 in the wafer transfer position 107 and a wafer boat 109 in a wafer boat transfer position 110. The wafer boat 109 may be configured for supporting a plurality of substrates in a spaced apart configuration, for example a vertically spaced apart configuration. The wafer boat 109 may be configured to support, for example, at least 100, at least 120, or at least 150 wafers. The wafers may comprise any combination of product wafers, test wafers, and/or heat shields.

The wafer handling robot 108 may be configured for transferring the wafers one by one, i.e., individually, from the wafer cassette 105 into a first wafer boat 109 located in the wafer boat transfer position 110 positioned for receiving the wafers. This may be performed until each wafer receiving position of the wafer boat 109 contains a wafer. In some embodiments, some wafer receiving positions may be designated as not requiring a wafer to be inserted therein. The wafer handling robot 108 may be configured for transferring wafers into a predetermined set of wafer receiving positions.

The wafer boat 109 may be positioned on a wafer boat handling device 113. The wafer boat handling device 113 may comprise the wafer boat transfer position 110.

Once loaded with wafers, a wafer boat 109 may be transferred into a process chamber 114 for processing wafers. The wafer boat handling device 113 may be positioned under a process chamber 114 (shown by dashed lines in FIG. 1). The wafer boat handling device 113 may comprise a wafer boat elevator (not shown) configured to transfer a wafer boat 109 from the wafer boat handling device 113 to the process chamber 114 and vice versa. The wafer boat handling device 113 may comprise more than one wafer boat position including the wafer boat transfer position 110. For example, the wafer boat handling device 113 may comprise one or more of a cooling position and a loading position. The wafer boat handling device 113 may comprise a rotatable table for rotating a wafer boat 109 between a wafer boat transfer position 110 and another position, e.g. a loading position at which the wafer boat 109 may be loaded, e.g. elevated, into the process chamber 114.

The semiconductor processing apparatus 101 may comprise more than one process chamber 114 and corresponding wafer boat handling device 113.

A wafer mapping apparatus according to embodiments of the present invention may be provided in a semiconductor processing apparatus, for example but not limited to the semiconductor processing apparatus 101 as described in relation to FIG. 1. The wafer mapping apparatus may comprise a light source configured to emit light towards a wafer carrier; imaging means configured to receive light emitted by the light source and reflected at the wafer carrier; and a plate that partially obstructs light emitted by the light source. The wafer mapping apparatus may be configured to acquire an image of a wafer carrier, e.g. a wafer boat such as wafer boat 109, and to determine a parameter of the image of the wafer carrier. In some embodiments, the parameter may be representative of presence of a wafer at a wafer receiving position in the wafer carrier. In some embodiments, the parameter may be representative of absence of a wafer at a wafer receiving position in the wafer carrier. In some embodiments, the parameter may be representative of presence of more than one wafer at a same wafer receiving position in the wafer carrier. In some embodiments, the parameter may be representative of a wafer being cross-slotted, that is, received in a non-horizontal position in the wafer carrier. Once the parameter of the image of the wafer carrier is determined, operations may be carried out to rectify incorrect wafer positioning, for example by removing a wafer from a double-slotted wafer receiving position; by removing and optionally re-inserting a cross-slotted wafer; by inserting a wafer into an empty wafer receiving position. Such operations may be carried out, for example, by the wafer handling robot 108.

A wafer handling apparatus according to embodiments of the present invention may be provided in a semiconductor processing apparatus, for example but not limited to the semiconductor processing apparatus 101 as described in relation to FIG. 1. The wafer handling apparatus may comprise the wafer handling robot 108 supported on the elevator for moving the wafer handling robot 108 in a vertical direction, and a wafer mapping apparatus 115, wherein the light source, imaging means, and plate are supported on the elevator. A vertical position of the wafer mapping apparatus 115, and therefore a location of the wafer carrier which is imaged by the imaging means, may be controlled by controlling the elevator so as to move the wafer mapping apparatus 115 to a specific vertical position. This may allow all wafer receiving positions of a wafer carrier to be imaged. By imaging the wafer carrier, determining one or more parameters of the image(s), and rectifying incorrect wafer positioning, for example using the wafer handling robot, a wafer carrier with correct wafer positioning can be provided to a process chamber, for example process chamber 114, of a semiconductor processing apparatus, for example semiconductor processing apparatus 101. This can allow for increase in throughput and decrease in wafer breakage or damage.

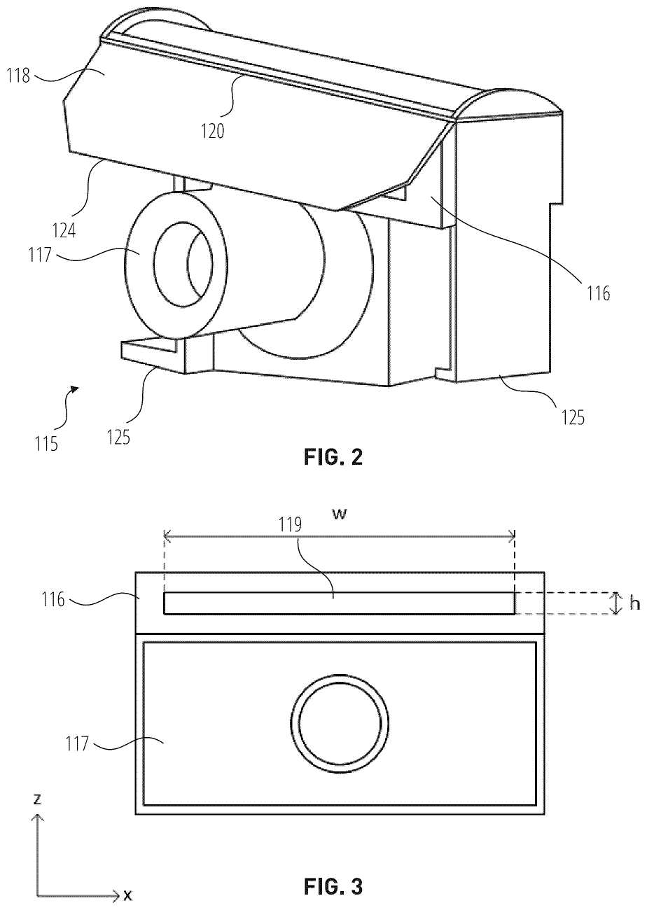

Referring to FIG. 2 and FIG. 3, a wafer mapping apparatus 115 according to embodiments of the present invention comprises a light source 116, imaging means 117, and a plate 118. The light source 116 is configured to emit light towards a wafer carrier, for example a wafer boat. In some embodiments, the light source 116 is configured to emit light towards wafer boat 109 in semiconductor processing apparatus 101. In some embodiments, the light source 116 is configured to emit white light. In some embodiments, the light source 116 is configured to emit light in the ultraviolet wavelength range. In some embodiments, the light source 116 is configured to emit light in the infrared wavelength range. The emission spectrum of the light source 116 may be chosen depending on properties of the wafers to be imaged. For example, if the wafers are made of silicon carbide, a light source 116 configured to emit light in the ultraviolet wavelength range may be used. The light source 116 may be a diffuse light source. The light source 116 may comprise light-emitting diodes (LEDs). The light source 116 may comprise a fluorescent tube. The light source 116 may comprise a non-diffuse light emitting component and a diffuser placed in front of the non-diffuse light emitting component so as to provide diffuse light after the diffuser. The light source 116 may be configured to emit a light beam having a beam width in a horizontal, e.g. x, direction which is at least twice, at least three times, at least four times, or at least five times a beam height in the vertical, e.g. z, direction. The light source 116 may comprise a light emitting surface 119 through which light is emitted. The light emitting surface 119 may have a width w in a horizontal direction and a height h in a vertical direction. The width w may be at least five times the height h.

The imaging means 117 is configured to receive light emitted by the light source 116 and reflected at the wafer carrier. The imaging means 117 may comprise, for example, a camera, a CCD sensor, a CMOS sensor, an array of photodiodes. The imaging means 117 may comprise one or more filters, such as bandpass filters, high pass filters, low pass filters, polarisers, spatial filters, neutral density filters. The imaging means 117 may be positioned below the light source 116. The light source 116 may be partially supported by the imaging means 117, for example by positioning the light source 116 directly on the imaging means 117. The light source 116 may be positioned on a support element (not shown) and the support element may be positioned on the imaging means 117.

The wafer mapping apparatus 115 comprises a plate 118 which is arranged to partially obstruct light emitted by the light source 116.

A wafer mapping apparatus 115 according to embodiments of the present invention comprising the plate 118 arranged to partially obstruct light emitted by the light source 116 allows for back reflections from elements other than the wafer carrier and wafers supported therein to be restricted or suppressed. This allows for clearer images of the wafer carrier and wafers supported therein to be acquired, with reduced noise due to back reflections from elements other than the wafer carrier and wafers supported therein. This may be particularly advantageous in a semiconductor processing apparatus which comprises various highly reflective components close to the wafer carrier. For example, a wafer boat handling device may be made of metal such as stainless steel; emitting light towards a wafer carrier supported on the wafer boat handling device may result in emitted light being reflected by both the wafer boat handling device and the wafer carrier and wafers supported therein. Light reflected by the wafer boat handling device may be detected by the imaging means and lead to noise in an image of the wafer carrier, resulting in a poor quality image and difficulty in extracting information about wafers supported in the wafer carrier from the image. A process chamber may have an outer surface made from a reflective material such as a metal and may present a similar problem. These problems may be solved by providing the plate 118 arranged to partially obstruct light emitted by the light source 116.

The plate 118 may be moveable so as to allow a degree of obstruction of the emitted light to be varied. For example, the plate 118 may be rotatably attached at an edge 120 of the plate to the light source 116 and may be rotatable about the edge 120. In this way, the light beam emitted by the light source 116 can be made narrower in the vertical direction.

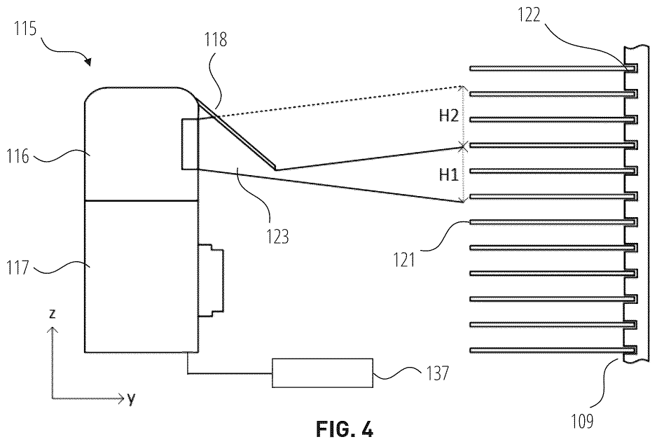

Referring to FIG. 4, narrowing of the light beam in the vertical direction due to controllable beam obstruction by the plate 118 is illustrated. The light source 116 emits light towards the wafer boat 109 which contains wafers 121 at wafer receiving positions 122. The light beam 123, if obstructed by the plate 118, has a height H1 close to the wafer boat 109. If not obstructed by the plate 118, the beam 123 has a height H1+H2 close to the wafer boat 109, at the same position in the y direction at which the height H1 is measured. It can be seen that, if only the wafers illuminated by the beam in the obstructed state are of interest, then obstructing the beam to the height H1 close to the wafer boat 109 provides less back reflection from objects not of interest, such as other wafers or other parts of the wafer boat 109, than when the beam is not obstructed, having height H1+H2 close to the wafer boat 109. The height H1 may be, for example, between one times and five times a distance between adjacent wafer receiving positions 122. The height H1 may be between one times and three times a distance between adjacent wafer receiving positions 122.

Referring again to FIG. 2, in some embodiments, the imaging means 117 and the light source 116 may be partially contained by a support 125. The support 125 may be configured to hold the imaging means 117 and the light source 116 in a fixed position relative to each other. The support 125 may enable the imaging means 117 and the light source 116 to be moved together without changing a position of the imaging means 117 and the light source 116 relative to each other. The plate 118 may be attached to the support at an edge 120. The plate may be attached to the light source at edge 120.

The plate 118 may be generally planar in shape. The plate 118 may have a light blocking edge 124 opposite to an edge 120 at which the plate 118 may be attached to the light source 116 or to a support 125. The light blocking edge 124 may be a straight edge. The light blocking edge may be arranged substantially parallel to a direction which is perpendicular to the vertical direction and to a normal to the light emitting surface 119. This may enable the emitted light to be blocked in a uniform way, resulting in a uniform beam after the plate 118.

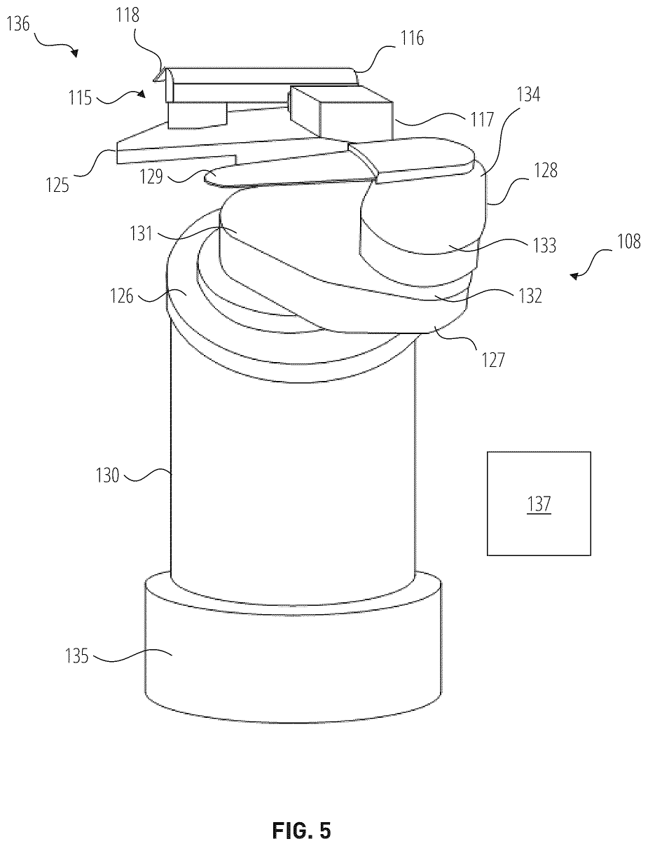

Referring to FIG. 5, embodiments of the present invention provide a wafer handling apparatus 136 comprising a wafer handling robot 108 and the wafer mapping apparatus 115. The wafer handling robot 108 may comprise a first arm 127 and a second arm 128, an end effector 129, and an elevator 130. The wafer handling robot 108 may comprise a support plate 126 on a top end of the elevator 130. The first arm 127 may have a first end 131 and a second end 132 opposite to the first end 131. The first end 131 of the first arm 127 may be rotatably linked to the support plate 126. The second arm 128 may have a first end 133 and a second end 134 opposite to the first end 133. The first end 133 of the second arm 128 may be rotatably linked to the second end 132 of the first arm 127. The second end 134 of the second arm 128 may be rotatably linked to the end effector 129. The end effector 129 may be configured to support a wafer. The end effector 129 may have, for example, a fork shape or a triangle shape. Other end effector shapes and forms may be used in embodiments. The elevator 130 may be supported by a pedestal 135.

Referring again to FIG. 4, the wafer mapping apparatus 115 may comprise a controller 137 for controlling operation of the wafer mapping apparatus 115. The controller 137 may be configured to cause the imaging means 117 to acquire an image of a wafer carrier, such as wafer boat 109, and to determine a parameter of the image of the wafer carrier. For example, the controller 137 may comprise a computer-readable medium on which is stored one or more sets of instructions or software, which, when executed by a computer, which may be comprised in the controller 137, cause the computer to perform operations for determining a parameter of an image of a wafer carrier acquired by the imaging means. The one or more sets of instructions or software may cause the computer to perform operations for changing a position and/or pose of the wafer handling robot 108 in dependence upon the parameter of the image of the wafer carrier. For example, the one or more sets of instructions or software may cause the computer to transmit a signal, data, or instructions to a controller configured to control the wafer handling robot 108 and/or elevator 130.

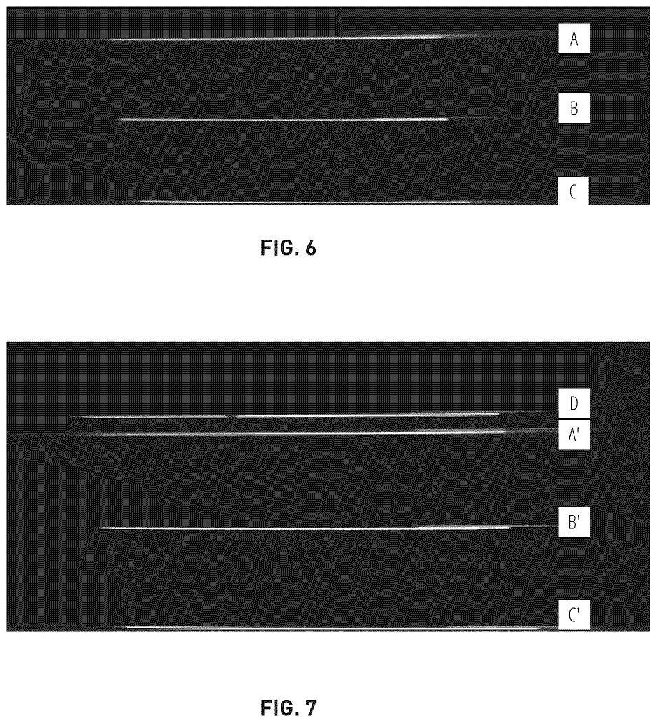

An example of an image of a wafer carrier acquired by the imaging means 117 is shown in FIG. 6. The wafers are seen as bright horizontal lines. In the image of FIG. 6, three wafers A, B, and C are correctly slotted with one wafer per wafer receiving position. A further example of an image of a wafer carrier acquired by the imaging means 117 is shown in FIG. 7. Wafers A′, B′, C′, and D are seen in the image. In this image, double slotting is observed, as the spacing between the top two wafers D and A′ is smaller than the spacing between two singly slotted wafers in adjacent wafer receiving positions, for example between wafers A′ and B′ or B′ and C′. By imaging the wafer carrier in a direction which is substantially parallel to a plane of a wafer receiving position, for example at an angle of at most 10°, more preferably at most 5°, even more preferably at 0°, a wafer, if present in the wafer receiving position, may be imaged substantially along its edge. This can allow for a wafer position in the wafer carrier to be easily determined, as compared with imaging the wafer in a direction which is not substantially parallel to the wafer receiving position in which it is received.

The operations for determining a parameter of the image may comprise detecting a presence or absence of a contour in the image. The operations for determining a parameter of the image may comprise detecting a presence or absence of a contour at a particular position in the image. The operations for determining a parameter of the image may comprise detecting a presence or absence of a contour at a centre position in the image. In some embodiments, the imaging means 117 may be positioned so as to acquire an image at the centre of which a wafer is expected to be detected, and so detection of a contour at a centre position of the image may indicate whether a wafer is present at the expected position. If a contour is not detected, it may be concluded that no wafer is present at the expected position. A contour may be detected by applying any suitable algorithm or method.

The operations for determining a parameter of the image may comprise detecting all contours in the image. A threshold may be applied so as to only detect contours of wafers, for example if the image comprises reflections from parts of the wafer boat, which may be less intense than reflections from the wafer edges.

The operations for determining a parameter of the image may comprise, if a contour is detected, fitting a line to the contour. By fitting a line to the contour and comparing the line to a reference, for example to a vertical line aligned with the z direction or to a horizontal line perpendicular to the z direction, an orientation of the wafer to which the contour corresponds can be determined. For example, if an angle between the contour and the horizontal direction is greater than a threshold value, it may be determined that the wafer is cross-slotted, that is, having one edge of the wafer at a first wafer receiving position and a second edge of the wafer at a second wafer receiving position different to the first wafer receiving position so that the wafer is not oriented with its plane perpendicular to the vertical direction.

In some embodiments, the reference to which the fitted line may be compared may be a line which intersects opposite ends of the fitted line and the parameter determined may be representative of a degree of curvature or warpage of the wafer. For example, a deviation of the fitted line from the line intersecting opposite ends of the fitted line may be determined as a function of distance along the fitted line. For example, a maximum deviation of the fitted line from the line intersecting opposite ends of the fitted line may be determined. In some embodiments, a wafer may be expected to be located at a particular position in the image under the assumption that the wafer is correctly slotted and not warped or curved. A position of the fitted line in the vertical direction may be compared with the expected wafer position and if the difference between the two positions is greater than a first threshold value and less than a second threshold value, it may be determined that the wafer is correctly slotted (due to the difference being less than the second threshold value) but is warped or curved (due to the difference being greater than the first threshold value).

The operations for determining a parameter of the image may comprise detecting all contours in the image, fitting lines to each of the contours, and comparing a position of the contours in the image to a reference. For example, it may be expected that each wafer receiving position contains exactly one wafer. An image of part of the wafer boat 109 spanning a number of wafer receiving positions, for example one wafer receiving position, or between one and ten wafer receiving positions, may be acquired by imaging means 117. All contours in the image may be detected and lines may be fitted to each of the contours, each fitted line representing one wafer. The positions of the fitted lines in the image may be compared with expected positions of wafers if all wafers were correctly slotted. Deviation from the expected wafer configuration may be determined based on, for example, a fitted line for a wafer being more than a threshold distance away from its expected position.

The operations for determining a parameter of the image may comprise providing the image to a neural network configured to receive an image of a wafer carrier as input and to output a parameter of the image. The neural network may be a neural network which has been trained on a set of images of a wafer carrier and corresponding image parameter(s) for each image. For example, the neural network may have been trained on a set of images of a wafer carrier, each image being associated with a parameter indicating presence or absence of a wafer at a particular position in the image. The neural network may have been trained on a set of images of a wafer carrier, each image being associated with a parameter indicating whether a wafer in the image has been correctly slotted oriented in a horizontal plane or has been cross-slotted. The neural network may have been trained on a set of images of a wafer carrier, each image being associated with a parameter indicating whether a single wafer or more than one wafer has been slotted at a particular position in the image. The neural network may have been trained on a set of images of a wafer carrier, each image being associated with a parameter representative of a shape of a wafer in the image.

Referring again to FIG. 5, in a wafer mapping apparatus 115 according to embodiments of the present invention, the light source 116, imaging means 117, and plate 118 of the wafer mapping apparatus 115 may be supported on the elevator 130 of the wafer handling robot 108. The light source 116, imaging means 117, and plate 118 of the wafer mapping apparatus 115 may be supported on a support plate 126 and the support plate may be supported on the elevator 130.

The wafer handling apparatus 136 may comprise a controller 137 for controlling operation of the wafer handling apparatus 136. The controller 137 may be configured to cause the imaging means 117 to acquire an image of a wafer carrier, such as wafer boat 109, and to determine a parameter of the image of the wafer carrier. For example, the controller 137 may comprise a computer-readable medium on which is stored one or more sets of instructions or software, which, when executed by a computer, which may be comprised in the controller 137, cause the computer to perform operations for determining a parameter of an image of a wafer carrier acquired by the imaging means 117. The one or more sets of instructions or software may cause the computer to perform operations for controlling a position and/or pose of the wafer handling robot 108 in dependence upon the parameter of the image of the wafer carrier. For example, the computer may be caused to, if the determined parameter of the image of the wafer carrier indicates that more than one wafer is present at a single wafer receiving position in the wafer carrier, perform operations for controlling a position and/or pose of the wafer handling robot 108 so as to move the end effector to a position slightly below a top wafer of the two wafers present at a single wafer receiving position, to move the end effector 129 upwards, e.g. by causing the elevator to move the wafer handling robot 108 upwards so as to cause the top wafer to be supported on the end effector 129, to move the end effector 129 to a position adjacent to a wafer storage position, for example a wafer cassette 105, and to deposit the wafer at the wafer storage position. In some embodiments, a position and/or pose of the wafer handling robot 108 may be controlled so as to position the end effector supporting the top wafer adjacent to an empty wafer receiving position and to deposit the wafer at the empty wafer receiving position.

In some embodiments, the computer may be caused to, if the determined parameter of the image of the wafer carrier indicates that a wafer is cross-slotted in the wafer carrier, perform operations for controlling a position and/or pose of the wafer handling robot 108 so as to move the end effector to a position slightly below the cross-slotted wafer, to move the end effector 129 upwards, e.g. by causing the elevator to move the wafer handling robot 108 upwards so as to cause the wafer to be supported on the end effector 129, to move the end effector 129 to a position adjacent to a wafer storage position, for example a wafer cassette 105, and to deposit the wafer at the wafer storage position. In some embodiments, a position and/or pose of the wafer handling robot 108 may be controlled so as to position the end effector supporting the wafer adjacent to an empty wafer receiving position in the wafer carrier and to deposit the wafer at the empty wafer receiving position.

In some embodiments, the one or more sets of instructions or software stored in the controller 137 may cause the computer to perform operations for controlling a vertical position of the wafer mapping apparatus 115. For example, in some embodiments, the wafer mapping apparatus 115 may be disposed on elevator 130 and the vertical position of the wafer mapping apparatus 115 may be controlled by controlling operation of the elevator 130. The one or more sets of instructions or software stored in the controller 137 may cause the computer to perform operations for i) causing the wafer mapping apparatus 115 to acquire an image of a wafer carrier using imaging means 117 and to determine a parameter of the image of the wafer carrier, and ii) causing a position of the wafer mapping apparatus 115 in the vertical direction to be changed. Steps i) and ii) may be repeated so as to cause images of the wafer carrier at different vertical positions of the wafer carrier to be acquired and analysed. In this way a map of the wafer carrier and wafers supported therein may be acquired.

In some embodiments, before wafer mapping is performed, the controller 137 can execute an exposure-time calibration routine for the imaging means 117. The exposure time can determine an amount of reflected light captured during image acquisition, and the calibration routine can be configured to reduce the likelihood of acquiring images that are excessively bright or excessively dark and, as a result, unsuitable for subsequent contour detection or other image analysis. In some embodiments, the exposure-time calibration can be performed using a representative wafer cassette 105 location and a representative wafer boat 109 location, for example where background reflections are expected to be substantially similar to background reflections at other corresponding locations. In some embodiments, location-specific calibration data can additionally or alternatively be stored for one or more particular wafer boat locations. A calibration wafer can be placed in a selected slot for the calibration routine, and the wafer can be oriented such that a notch or flat portion is not positioned toward the imaging means 117 so as to reduce an influence of wafer orientation on the calibration result.

In some embodiments, the controller 137 may first verify proper operation of the imaging means 117 before determining the exposure time, for example by causing the imaging means 117 to acquire a plurality of images at an exposure time of zero. If a wafer contour, blob, or other image feature is detected in one or more of the images acquired at zero exposure time, the controller 137 can determine that the imaging means 117 is malfunctioning. If proper operation is verified, the controller 137 can acquire a plurality of images at each of a plurality of increasing exposure settings. For each exposure setting, the controller 137 may determine a width of a detected wafer feature and may disregard exposure settings for which no wafer feature is detected or for which a variation in the detected width across the plurality of images exceeds a threshold value, indicating insufficient repeatability. In some embodiments, a representative width for each exposure setting can be determined as a median of the detected widths so as to reduce the influence of outliers.

In some embodiments, the controller 137 can determine a calibrated exposure time based on a change in detected wafer width with increasing exposure time. As the exposure time is increased, the detected width may initially increase and may then approach a stable level corresponding to detection of substantially all light reflected by the wafer edge towards the sensor of the imaging means 117. At still higher exposure times, the detected width may increase again due to contributions from reflections from components surrounding the wafer, for example reflective surfaces on the interior of the semiconductor processing apparatus 101. Accordingly, the controller 137 may be configured to determine a rate of change of the detected width with respect to exposure time and may identify a first sequence of exposure settings for which the rate of change is below a predetermined threshold value. The calibrated exposure time can then be selected from within that sequence, for example from a median exposure setting in the sequence, so as to avoid selecting an exposure setting at an edge of the stable region. This exposure time calibration may enable the controller 137 to select an exposure time at which the wafer edge is sufficiently illuminated for repeatable reliable detection while avoiding exposure settings at which the detected width varies for a set exposure time due to insufficient illumination, or is artificially high due to reflections from components surrounding the wafer.

The threshold value and the number of consecutive exposure settings considered can be selected empirically and can depend on the imaging means 117 and the wafer handling environment. In some embodiments, the calibrated exposure time can be determined once before the wafer mapping apparatus 115 is enabled for wafer mapping and can be stored by the controller 137 for subsequent image acquisition.

In some embodiments, before wafer mapping is performed, the controller 137 may execute a calibration routine for correlating image measurements produced by the imaging means 117 with physical displacement of the wafer mapping apparatus 115 in the vertical direction. During a pixel-to-distance calibration, the wafer mapping apparatus 115 may be moved relative to the wafer boat 109 to a plurality of z positions by the elevator 130 while the imaging means 117 acquires images at the respective z positions. The controller 137 may detect one or more wafer contours in the acquired images and may determine an apparent displacement of the wafer contours in pixels relative to a commanded z displacement of the wafer mapping apparatus 115. From these measurements, the controller 137 may determine a conversion factor representative of pixels per unit distance or distance per pixel. In some embodiments, the conversion factor may be determined from an average of measurements acquired at a nominal z position and at offset positions above and below the nominal z position. The conversion factor may be stored and subsequently used in post-processing of acquired images and in determining wafer position, slot occupancy, wafer curvature, or other image parameters.

In some embodiments, the controller 137 may further perform a pose calibration in the vertical direction and in a rotational (theta) direction about the z axis to establish a viewing pose at which a wafer 121 is positioned near a center region of the image, so as to improve wafer edge detection. The rotational direction theta corresponds to rotation about a z-axis extending in the z direction and centered on the wafer handling robot 108 or on a wafer manipulator of the wafer handling robot 108. The calibration may begin from a nominal pose and may include causing the wafer handling robot 108 to vary z and theta while acquiring images and determining one or more image parameters from the acquired images. The theta position may be adjusted to increase a detected width or extent of a wafer edge feature in the image, which may correspond to an improved viewing angle for edge detection. The z position may be adjusted to reduce an offset between a measured wafer position in the image and an expected wafer position, for example until a residual error is less than a predetermined threshold. Positioning the wafer near the center region of the image may reduce distortion and may improve repeatability of contour detection and line fitting.

In some embodiments, calibration data obtained by the controller 137 may be stored as part of calibration data associated with a selected wafer mapping scenario. The calibration data may be associated with a particular wafer carrier configuration, cassette configuration, and/or wafer size, such that different conversion factors or pose settings can be used for different wafer handling conditions. When a corresponding wafer carrier and wafer size are to be processed, the controller 137 may retrieve the stored calibration data and operate the wafer mapping apparatus 115 using the retrieved calibration values. This may improve consistency of wafer detection and mapping across different hardware configurations and wafer formats.

The wafer handling apparatus 136 may comprise a first controller for controlling operations of the wafer mapping apparatus 115 and a second controller for controlling operations of the wafer handling robot 108. The first controller may be configured to send instructions to the second controller based on a determined parameter of an image of the wafer carrier acquired by the wafer mapping apparatus 115.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A wafer mapping apparatus comprising:
a light source configured to emit light towards a wafer carrier;
imaging means configured to receive light emitted by the light source and reflected at the wafer carrier; and
a plate arranged to partially obstruct light emitted by the light source.

2. The wafer mapping apparatus of claim 1, wherein the plate is moveable so as to vary a degree of obstruction of light emitted by the light source.

3. The wafer mapping apparatus of claim 1, wherein the light source is positioned above the imaging means.

4. The wafer mapping apparatus of claim 3, wherein the light source is partially supported by the imaging means.

5. The wafer mapping apparatus of claim 1, wherein the imaging means and the light source are partially contained by a support, wherein the plate is attached to the support.

6. The wafer mapping apparatus of claim 1, wherein the plate is attached to the light source.

7. The wafer mapping apparatus of claim 15, wherein the light source comprises a light emitting surface having a width and a height, wherein the width is at least five times the height.

8. The wafer mapping apparatus of claim 1, comprising a computer-readable medium on which is stored one or more sets of instructions or software, which, when executed by a computer, cause the computer to perform operations for determining a parameter of an image of a wafer carrier acquired by the imaging means.

9. The wafer mapping apparatus of claim 8, wherein the operations comprise:
obtaining an image of a wafer carrier; and
detecting a presence or absence of a contour in the image.

10. The wafer mapping apparatus of claim 9, wherein the operations comprise, if a presence of a contour in the image is detected, fitting a line to the contour.

11. The wafer mapping apparatus of claim 10, wherein the operations comprise determining a parameter of the image based on the line fitted to the contour.

12. The wafer mapping apparatus of claim 11, wherein the parameter is indicative of a position of a wafer in the wafer carrier.

13. A wafer handling apparatus comprising a wafer handling robot and the wafer mapping apparatus of claim 8, wherein the one or more sets of instructions or software, when executed by the computer, cause the computer to perform operations for controlling a position of the wafer handling robot in dependence upon the parameter of the image of the wafer carrier.

14. The wafer handling apparatus of claim 13, wherein the one or more sets of instructions or software, when executed by the computer, further cause the computer to determine a calibrated exposure time by determining a rate of change of a detected wafer width with respect to exposure time, identifying a first sequence of exposure settings for which the rate of change is below a predetermined threshold value, and selecting the calibrated exposure time from within the first sequence.

15. A wafer handling apparatus comprising:
a wafer handling robot comprising at least two rotatably linked arms, an end effector attached to one of the arms, and an elevator for varying a vertical position of the at least two rotatably linked arms and the end effector; and
the wafer mapping apparatus of claim 1, wherein the light source, imaging means, and plate are supported on the elevator.

16. The wafer handling apparatus of claim 15, further comprising a controller configured to control a position of the wafer mapping apparatus in the vertical direction by controlling the elevator, wherein the controller is further configured to repeat, at least once, the steps of:
causing the wafer mapping apparatus to acquire an image of a wafer carrier using the imaging means and to determine a parameter of the image of the wafer carrier;
causing a position of the wafer mapping apparatus in the vertical direction to be changed.
